(19) United States
(12) Patent Application Publication
(10) Pub. No.: US 2019/0324071 A1
(43) Pub. Date: Oct. 24, 2019

(54) ELECTRICITY METERING DEVICE

(71) Applicant: GULPLUG, Grenoble (FR)

(72) Inventor: Vianney Poiron, Grenoble (FR)

(21) Appl. No.: 16/311,304

(22) PCT Filed: Jun. 14, 2017
(86) PCT No.: PCT/FR2017/051540

§ 371 Date: Dec. 19, 2018

(30) Foreign Application Priority Data
Jun. 20, 2016 (FR) 1655734

(51) Int. Cl. G01R 22/06; G01R 21/06; G01R 15/18

(52) U.S. Cl. CPC G01R 22/063; G01R 15/183; G01R 21/06

(57) ABSTRACT

A method for metering consumption of electrical energy includes charging a first store, thereby causing the first store to store electrical energy, transferring energy stored in the first store to a second store when a voltage across terminals of the first store reaches a pre-determined threshold, and using a transmitter, transmitting a message when both data representing a duration has reached a threshold value and when a voltage at terminals of the second store has exceeded a pre-determined threshold.

### RELATED APPLICATIONS

This is the national stage, under § 371, of international application PCT/FR2017/051540, filed on Jun. 14, 2017, which claims the benefit of the Jun. 20, 2016 priority date of French Application 1655734.

### FIELD OF INVENTION

This invention relates to measurement devices and, in particular, to devices for measuring current flowing through an electrical conductor.

### BACKGROUND

To promote energy efficiency of electrical equipment, it is useful to monitor its energy consumption and to transmit information indicative of that energy consumption to a location at which decisions concerning the operation of such equipment. Doing so requires some kind of meter that will measure energy consumption.

### SUMMARY

The invention concerns an electrical energy metering device that can transmit messages at a low bit-rate on a long-range cellular network while avoiding the complexity of having an external power source.

Transmitting a message on a long-range network requires a significant amount of energy. To supply this energy, a meter as described herein includes first and second energy stores. The first energy store is not sufficient to be used for message transmission. It can be used for simple metering. The second energy store, on the other hand, progressively collects and stores energy from the first energy store at each charging and discharging cycle.

The invention thus allows a simple solution to be maintained for metering electrical energy using the first store while allowing a message to be transmitted on a long-range network and while maintaining a fully autonomous device that avoids the need for an external power source.

In one aspect, the invention features a current sensor configured to supply a secondary current from a primary electric current flowing through an electrical conductor; a primary electrical energy storage unit connected to the current sensor and configured to store an amount of electrical energy from the secondary electrical current; a voltage threshold detection unit connected to the primary electrical energy storage unit and configured to detect an exceedance of a voltage threshold at the terminals of the primary electrical energy storage unit; a processing unit connected to the primary storage unit; first switching means controlled by the voltage threshold detection unit and configured to trigger a supply of electric power to the processing unit when the voltage threshold at the terminals of the primary electrical energy storage unit is exceeded; a first wireless data transmitter connected to the processing unit and configured to send a message containing data representing the electric current flowing through the electrical conductor; a secondary electrical energy storage unit connected to the primary storage unit; a unit for measuring the voltage at the terminals of the secondary storage unit; second switching means configured to be controlled by the processing unit and configured to trigger a transfer of energy from the primary storage unit to the secondary storage unit and to trigger a supply of power to the first wireless data transmitter when the voltage measured at the terminals of the secondary storage unit by the measurement unit exceeds a threshold, with a view to transmitting a message containing data representing the electric current flowing through the electrical conductor.

In some embodiments, the processing unit comprises a microprocessor and a non-volatile memory with the microprocessor being configured to increment an energy meter on completion of each charging cycle of the primary storage unit.

In other embodiments, the device comprises a second wireless data transmitter connected to the processing unit and the microprocessor is configured to instruct a message to be transmitted using the second transmitter on completion of a charging cycle of the primary storage unit. Among these are embodiments in which the second transmitter is configured to operate on a short-range network, selected from Zigbee, ZigBee Green Power, Bluetooth, “Bluetooth Low Energy” or Wi-Fi.

In some embodiments, the first transmitter is configured to operate on a long-range network of LPWAN type.

Some embodiments include a discharging unit connected to the primary storage unit and controlled by the processing unit to discharge the primary storage unit.

In some embodiments, the processing unit is configured to determine a data item representing a duration.

In other embodiments, the data item representing a duration corresponds to a meter of the number of charging cycles of the primary storage unit.

Other embodiments include a clock that allows the data item representing a duration to be determined.

In some embodiments, the secondary storage unit comprises at least one super-capacitor.

Other embodiments include a rectifier circuit connected to the current sensor to rectify the secondary current generated by the current sensor.

Still other embodiments have a near field communication circuit connected to a memory of the processing unit.

The invention also relates to an electrical energy metering method implemented using the device as defined above, the method comprising charging the primary storage unit to store an amount of electrical energy from the secondary electric current; transferring electrical energy from the primary storage unit to the secondary storage unit when the voltage at the terminals of the primary storage unit reaches a determined threshold; transmitting a message using the first transmitter when a data item representing a duration has reached a threshold value and when the voltage at the terminals of the secondary storage unit has exceeded a determined threshold.

In some practices, the data item representing a duration corresponds to a meter of the number of charging cycles of the primary storage unit.

In other practices, the data item representing a duration corresponds to an elapsed duration determined using a clock.

As used herein, “short range” refers to several tens of meters inside and up to 300 meters outside. For example: ZigBee, ZigBee Green Power, Bluetooth, BLE (Bluetooth Low Energy), Wi-Fi, etc.

As used herein, “long-range” means several kilometers. In particular, this will involve LPWAN (Low Power Wide Area Network) technology, which includes, for example, networks of LoRa and SigFox type.

The invention relates to an electrical energy metering device operating through a wireless communication network with a view to allowing the transmission of messages, for example, that are intended for a central station intended for managing electrical energy of an electrical grid (of “Smart Grid” or “Smart City” type). Preferably, the communication network will be a long-range and low bit rate communication network of LPWAN (Low Power Wide Area Network) type and based on a protocol such as LoRaWAN (Long Range Wide Area Network) or that developed by SigFox or Qowisio.

Some practices further include discharging the primary storage unit that is implemented after the step of transferring energy from the primary storage unit to the secondary storage unit or of transmitting a message.

### BRIEF DESCRIPTION OF THE FIGURES

Further features and advantages will become apparent from the following detailed description, which is provided with reference to the accompanying drawings, in which:

FIG. 1 shows a first embodiment of a meter for metering electrical energy;

FIG. 2 shows a flowchart of the operation of the meter shown in FIG. 1;

FIGS. 3A and 3B show timing diagrams that illustrate the principle of operation of the meter in FIG. 1;

FIG. 4 shows a second embodiment of the meter;

FIG. 5 shows a flowchart of the operation of the meter shown in FIG. 1;

FIG. 6 show an alternative embodiment of the meter shown in FIG. 4;

FIG. 7 shows a flowchart of the operation of the meter shown in FIG. 6; and

FIG. 8 shows an alternative embodiment of the meter shown in FIG. 6.

### DETAILED DESCRIPTION

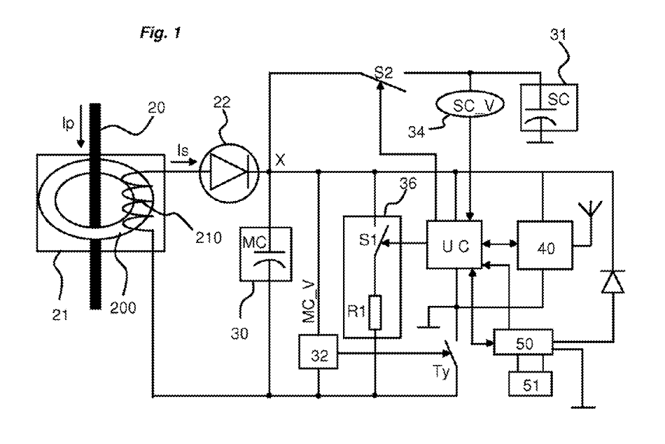

FIG. 1 shows a meter that has a casing that is claimed or positioned on an electrical conductor 20, hereafter referred to as simply a “conductor.” The conductor 20 carries an AC primary current Ip to power certain equipment. The primary current Ip couples to the casing and thus provides a way to measure data related to the primary current Ip, and in particular, energy consumed by the equipment. The meter also permits sending of an energy index and other data, such as temperature, acceleration, pressure, as well as levels of various gases, including carbon monoxide and carbon dioxide. In addition, the AC primary-current Ip induces an AC secondary-current Is that powers the meter.

In those embodiments that also have a real-time clock, it is possible to send other data pertaining to measured current, including effective values of maximum and minimum current flowing through the conductor 20 during a particular duration, effective value of average current through the conductor 20, and the presence of a current fault, which can be manifested by an over-current followed by a zero-crossing of the current's waveform.

The meter includes two electrical energy storage units that capture and store electrical energy. These will be referred to as the “first store 30” and the “second store 31.”

The first store 30 captures energy from the secondary current Is and uses it to power a processor UC and the second store 31 through transmission of an instruction from the processor UC. The second store 31 powers a transmitter 40 to transmit messages on a communication network when the second store 31 has enough energy to do so.

The meter includes a current sensor 21 that supplies the secondary current Is that represents and is induced by the primary current Ip. The current sensor 21 includes a core formed by a torus 200 through which the conductor 20 passes and a winding 210 around the torus 200. The conductor 20 thus forms the primary of a current transformer and the winding 210 forms the secondary of this current transformer. As a result, the secondary current Is the image of the primary current Ip. Within its casing, the meter includes an electronic circuit directly connected to the two ends of the winding 210.

The circuit includes a rectifier 22 that rectifies the secondary current Is. In some embodiments, the rectifier 22 comprises a diode or a diode bridge connected to the winding's first terminal. In other embodiments, the rectifier 22 comprises a diode or a diode bridge connected across both of the winding's terminals.

In the circuit shown in FIG. 1, the first store 30 comprises a first capacitor MC having a cathode that connects to the rectifier 22 and an anode that connects to the winding's second terminal.

The circuit also includes a threshold detector 32 that measures a voltage threshold. The threshold detector 32 connects in parallel with the first capacitor MC and determines whether a voltage MC_V across the first capacitor MC exceeds a threshold voltage MC_V_TH. The threshold detector 32 changes the state of a first switch Ty upon detecting that the first capacitor MC has exceeded a threshold voltage MC_V_TH. In some embodiments, a thyristor with its gate connected to the threshold detector's output implements the first switch Ty.

The second store 31 comprises a second capacitor SC having an anode that connects to a junction X between the first store 30 and the rectifier 22 via a second switch S2 and a cathode that connects to a voltage reference such as ground. In some embodiments, the second store 31 comprises a super-capacitor, such as a double-layer capacitor. However, the second store 31 can also be comprise a battery. A voltage meter 34 measures a voltage SC_V across the second store 31.

The processor UC includes at least one microprocessor and one non-volatile memory connected parallel to the first store 30. A suitable memory is a ferroelectric random access memory. When the first switch Ty closes, the processor UC receives power from the first store 30.

The processor UC includes an input that receives the voltage measured by the voltage meter 34. Each time the first capacitor MC charges, the processor UC increments an energy meter by an energy increment and stores an energy index. The energy index corresponds to a running sum of consumed electrical energy.

The processor UC controls the second switch S2 to cause charge from the first store 30 to move to the second store 31. The second switch S2 connects to the first store 30 at the junction point X where the rectifier 22 and the anode of the first capacitor MC connect. A suitable implementation of the second switch S2 is a MOS transistor with its gate connected to an output of the processor UC.

When the first switch Ty closes, the first store 30 connects to and thus provides power for a wireless transmitter 40. The processor UC uses the transmitter 40 to send a message on a wireless network containing information as described above concerning power consumption by the equipment. This message transmission occurs when sufficient energy is available in the second store 31.

The circuit includes a discharger 36 in parallel with the first capacitor MC. The discharger 46 includes a third switch S1 and a resistor R1 in series. A suitable third switch S1 is a transistor having its base or gate connected to an output of the processor UC. When the third switch S1 closes, the first capacitor MC discharges through the resistor R1.

In some embodiments, the circuit also includes a near-field-communication chip 50 having a processor and a memory and an near-field-communication antenna 51 to receive power for powering the near-field-communication chip 50, for example by a mobile terminal. As a result, the mobile terminal is able to directly power the near-field-communication chip 50 and the processor UC as well as the internal non-volatile memory, and in particular, the energy index. The near-field-communication link thus permits configuration of the meter in order to, for example, set threshold values.

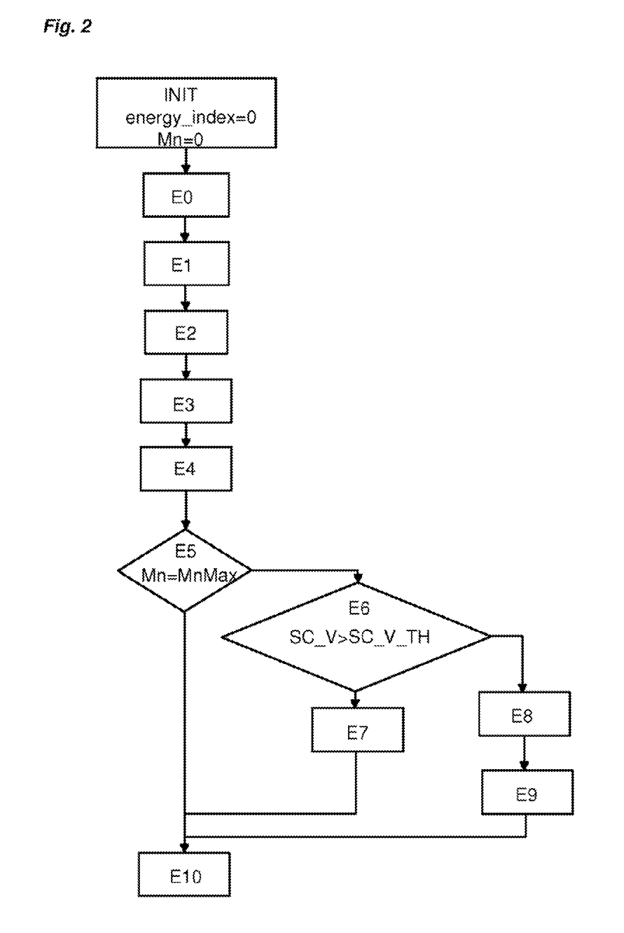

Referring now to FIG. 2, operation of the meter shown in FIG. 1 begins with an initial power-up (INIT) during which the processor UC sets an energy meter and a charge-cycle meter to zero. The energy meter, denoted energy_index, corresponds to the total amount of energy consumed by the equipment powered through the conductor 20. The charge-cycle meter meters charging cycles of the first capacitor MC.

Next, the secondary current Is charges the first store 30 (step E0).

When the voltage at the terminals of first store 30 reaches the threshold voltage MC_V_TH defined by the threshold detector 32, the threshold detector 32 closes the first switch Ty. This provides power to the processor UC (step E1).

The processor UC then increments the energy meter by a determined increment, “energy_increment” thus incrementing the value of the energy index “energy_index” by the value of the increment “energy_increment” (step E2).

Next, the processor UC increments the counter “Mn” by one unit (step E3).

The processor UC then closes the second switch S2. This allows energy from the first store 30 to be transferred to the second store 31 (step E4). The time that the second switch S2 remains open is short compared to the time needed to charge the first capacitor MC. Once this time lapses, the processor reopens the second switch S2.

Next, the processor UC compares the value of the counter Mn with a stored meter-threshold, MnMax (step E5).

If the counter Mn has not yet reached the stored meter-threshold MnMax, the processor UC terminates the cycle by closing the third switch S1, thereby discharging the first capacitor MC. The processor UC then begins a new cycle by charging the first capacitor MC (step E0).

On the other hand, if the counter Mn has reached the stored meter-threshold MnMax, then a certain duration has elapsed and that it is time to send a message. The processor UC then tests to see if enough energy is available in the second store 31 for transmitting a message (step E6).

If the voltage SC_V at the terminals of the second store 31 is lower than a stored voltage-threshold SC_V_TH, then the processor UC cannot send a message. Instead, it decrements the counter Mn by one unit (step E7). The processor UC then terminates the cycle by closing the third switch S1, thereby discharging the first capacitor MC (step E10 and begins a new cycle by charging the first capacitor MC all over again (step E0).

On the other hand, if it turns out that the voltage SC_V at the terminals of the second store 31 is higher than the stored voltage-threshold SC_V_TH, the processor UC resets the counter Mn to zero (step E8) and instructs a message to be transmitted (step E9).

To carry this out, the processor UC closes the second switch S2 to power the transmitter 40 using energy stored in the second store 31, generates the message, and causes transmission of the message.

The message includes data representing one or more of: the stored energy_index energy meter, a preamble, an item of synchronization data, an identifier of the transmitter device or of the source, data representing the energy meter and an item indicating end of transmission or of control data. EP 2354799 provides the example of an energy message structure that could be generated and transmitted.

Once the message is sent, the processor UC terminates the cycle by closing the third switch S1, thereby discharging the first capacitor MC (step E10). The processor UC then begins a new cycle by charging the first capacitor MC all over again (step E0).

At any time, if a mobile terminal is near the device and powers the near-field-communication chip 50, the up-to-date energy meter available in the non-volatile memory can be copied to the memory of the near-field-communication chip 50 in order to be read by the mobile terminal (step E3).

In a particular implementation, the primary current Ip is ten amperes, the secondary winding 210 has three thousand turns, the first capacitor MC is a tantalum capacitor with a 940-microfarad capacitance, the second capacitor SC is an EDLC super-capacitor with a 100-millifarad capacitance, the first capacitor's charging cycle is one second, the conduction duration of the second switch is two milliseconds, the stored meter-threshold MnMax is 7200, which is about two hours, the threshold voltage MC_V_TH is 2.9 volts, and the stored voltage-threshold SC_V_TH is 2.8 volts.

Each long cycle, on completion of which the transmitter 40 sends a message, is made up of MnMax short cycles, the number of such short cycles being configured through the near-field communication link. Its value is set based on the value of the primary current Ip.

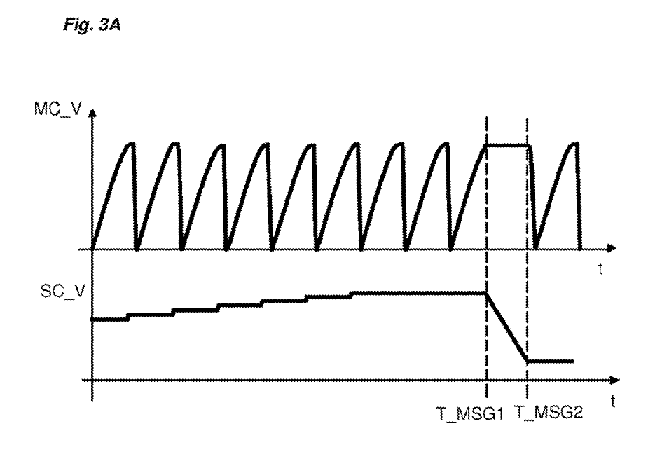

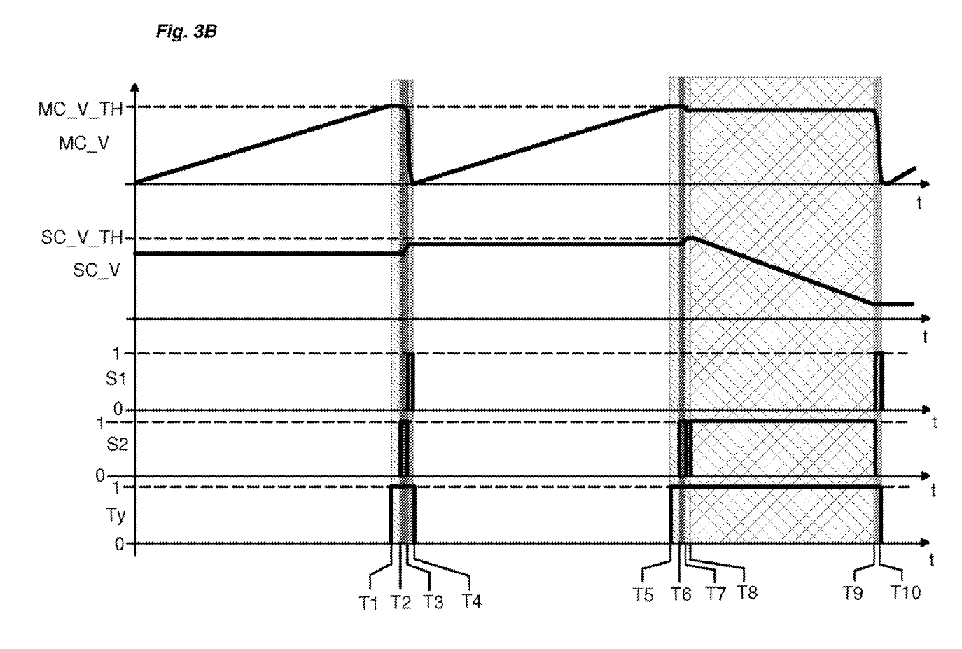

FIGS. 3A and 3B show the operation of the device as described above in connection with FIGS. 1 and 2.

In FIG. 3A, rectified current originating from the winding 210 charges the first capacitor MC. The resulting stored energy thus becomes available to power the electronics, and in particular, the processor UC.

A “cycle” of the first capacitor MC begins with the onset of charging and ends with the end of discharging. Upon completion of each such cycle, at least some energy stored in the first capacitor MC is transferred to the second store 31. As a result, the voltage across the terminals of the second store 31 progressively increases. When this voltage is high enough, i.e., higher than the stored value DC_V_TH, the second store 31 uses energy accumulated therein to enable the transmitter 40 to send a message at the instant T_MSG1. during the interval between T_MSG1 and T_MSG2 as shown in FIG. 3A.

In FIG. 3B, during the intervals from T1 to T2 and T5 to T6, while the first store 30 is charged sufficiently, the first switch Ty is in a first state that permits power to flow to the electronics and in particular to the processor UC. As a result, the processor UC can instruct the second switch S2 to close, thereby allowing energy to be transferred from the first store 30 to the second store 31. This occurs during the interval between T2 and T3 and between T6 and T7. This causes the voltage across the terminals of the second store 31 to increase.

Upon completion of energy transfer to the second store 31, the processor UC closes the third switch S1, thereby discharging the first capacitor MC of the first store 30. This occurs in the interval between T3 and T4.

When the voltage at the terminals of the secondary storage unit 31 reaches a sufficient level, namely at time T7, the microprocessor UC generates the message to be sent during the interval between T7 and T8. It also closes the second switch S2 to discharge the second store 31. This occurs in the interval between T8 and T9. This makes it possible to preserve, at the terminals of the first store 30, a voltage that is higher than the detection threshold thus allowing the first switch Ty to remain closed so that the transmitter 40 and the processor UC can be powered. This, in turn, permits message transmission in an interval between T8 and T9. Subsequently, the processor UC re-opens the second switch S2 and closes the third switch S1 to discharge the first capacitor MC. This occurs in an interval between T9 and T10.

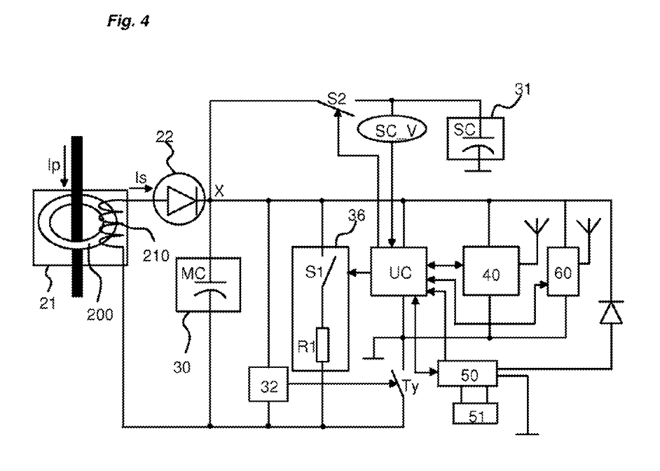

A second embodiment, shown in FIG. 4, adds a second transmitter 60 that transmits on a short-range wireless communication network. A suitable short-range wireless communication network is a radio frequency network that uses a low-consumption protocol. Examples include “Zigbee Green Power” networks and those with similar protocols. The other components remain unchanged.

In this second embodiment, the first and second transmitters 40, 60 are in parallel. This topology benefits from the two charging cycles of the first and second stores 30, 31 for transmitting information on a long-range network and/or on a short-range network. The first store 30 provides energy for the short cycle and the second store 31 provides energy for the second cycle as described in connection with FIG. 1. The dual transmission solution of the second embodiment multiplies the uses of the meter.

Depending on its location and the requirements, the device can operate in short-range mode, in long-range mode or in combined short and long-range modes. In the combined mode, for example, returning energy data on the short-range network in real time and returning energy data and alarms on the long-range network will be involved. These alarms can be, for example, abnormal average current levels.

FIG. 5 shows the procedure for operating the meter in FIG. 4. The procedure in FIG. 5 includes a step of having the processor UC cause the second transmitter 60 to transmit the “energy_index” when the electronics are powered by the first store 30 (step E15). The rest of the operation remains unchanged.

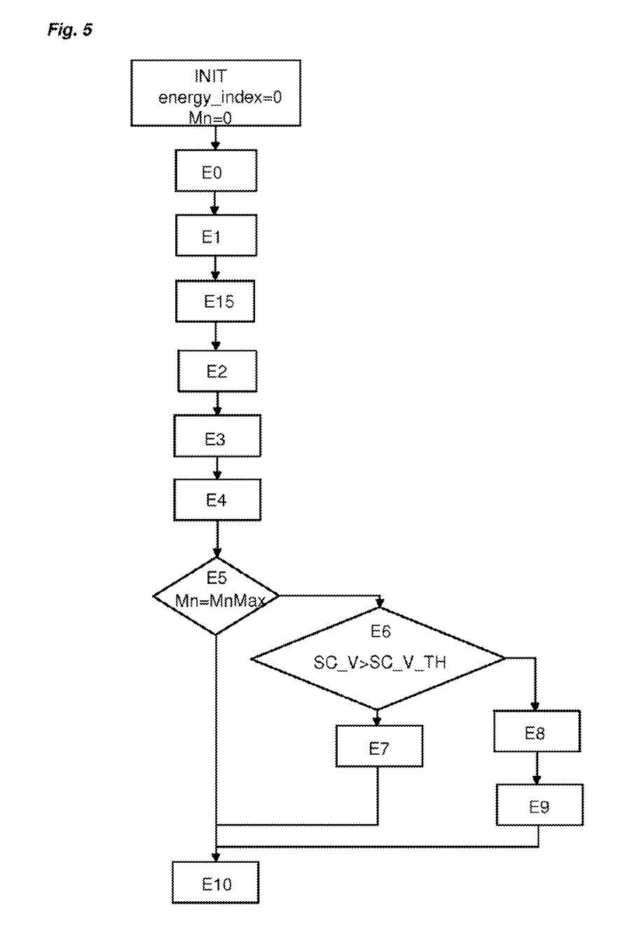

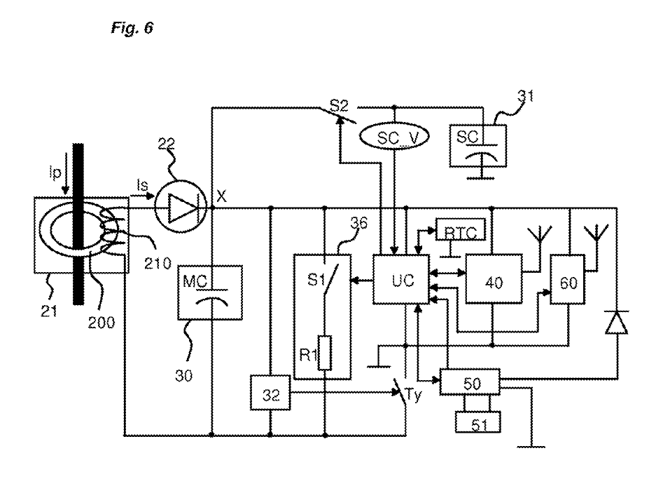

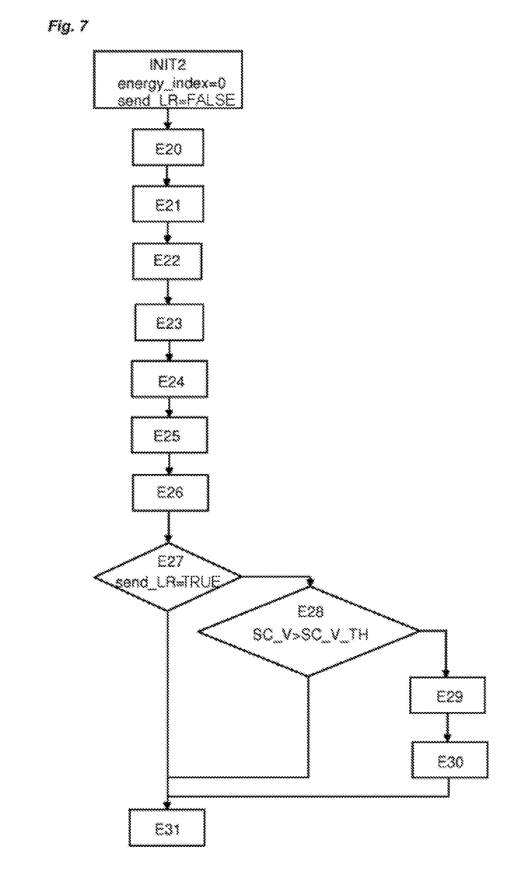

FIG. 6 shows a third embodiment similar to the second embodiment but with the addition of a real-time clock RTC to better regulation of sending of messages. When powered, the processor UC has read and write access to the clock RTC. In some embodiments, a battery powers the clock RTC.

In the first and second embodiments, what triggered message transmission was the counter Mn. In this third embodiment, which has a clock RTC, it is time that triggers transmission. Although the clock is particularly useful in an embodiment having first and second transmitters 40, 60, it can also be used in embodiments that only have the first transmitter 40. The use of a clock is described hereafter for a two-transmitter topology such as that described above in connection with FIG. 4.

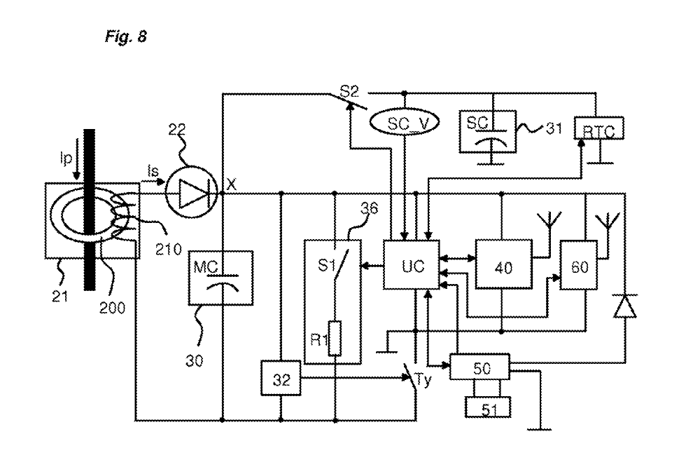

As shown in FIG. 8, on initial power-up (INIT2), the microprocessor sets the energy meter to zero so that energy_index=0 and sets “send_LR” to “FALSE”. The secondary current Is then charges the first store 30 (step E20).

When the voltage MC_V at the first store's terminals reaches the voltage threshold MC_V_TH defined by the threshold detector 32, the first switch Ty closes. This provides power to the processor UC (step E21).

The processor UC then increments the energy meter by a determined increment “energy_increment: so that energy_index=energy_index+energy_increment (step E22).

The processor UC then generates a message to be sent. This message includes data representing the stored energy meter, “energy_index”. The message can also include one or more of a preamble, synchronization data, a source identifier, a transmitter identifier, data representing the energy meter, data indicating of transmission, or control data.

The processor UC then instructs the second short-range transmitter 60 to transmit the generated message (step E24).

After having done so, the processor UC consults the clock RTC. If the clock RTC indicates a duration lower than a stored limit duration denoted T1, the processor UC does nothing. On the other hand, if the clock RTC indicates a duration greater than or equal to the stored limit duration T1, the processor UC sets send_LR to “TRUE” (step E25).

The processor UC subsequently closes the second switch S2 to transfer energy from the first store 30 to the secondary storage unit 31 (step E26). The conduction duration of the second switch S2 is low relative to the charging time of the first capacitor MC. Once the conduction duration is complete, the processor UC re-opens the second switch S2.

The processor UC then tests the value of send_LR (step E27). If send_LR is “FALSE,” then the processor UC closes the third switch S1, thus discharging the first capacitor MC and terminating the cycle (step E31). The processor UC then begins a new cycle by charging the capacitor MC. On the other hand, if send_LR is “TRUE,” this means that a certain duration has elapsed and that it is time to send a message. The processor UC then performs a test in order to know whether the energy available in the secondary store 31 is sufficient for transmitting a message (step E28).

If the voltage at the terminals of the secondary storage unit 31 is lower than a stored threshold value, “SC_V_TH”, then the processor UC cannot instruct a message to be transmitted. The processor UC terminates the cycle by instructing the capacitor of the first store 30 to discharge by closing the switch of the discharging unit (step E31). The processor UC can then begin a new cycle by charging the capacitor MC of the first store 30. In this situation, the variable send_LR thus remains at the value TRUE at the start of the following cycle.

If the voltage SC_V at the terminals of the secondary store 31 is higher than the stored threshold value SC_V_TH, the processor UC then assigns the value “FALSE” to the variable send_LR (step E29) and instructs a message to be transmitted (step E30).

To transmit the message, the processor UC closes the second switch S2 to enable the second store 31 to power the first transmitter 40. The processor UC then generates the message to be sent. This message includes representing the stored energy_index energy meter. The message can also include preamble, an item of synchronization data, an identifier of the transmitter device or of the source, data representing the energy meter, end of transmission data, or control data. After having done so, the transmitter 40 transmits the generated message.

At any time, if a mobile terminal is near the device and powers the near-field-communication chip 50, the up-to-date energy meter available in the non-volatile memory of the processing unit UC can be copied to the memory of the near-field-communication chip to be read by the mobile terminal (step E23).

While the foregoing embodiment can be implemented with a variety of parameter values, some embodiments have a primary current Ip of ten amperes that induces secondary current in a winding 210 having three-thousand turns. The first capacitor MC is a tantalum capacitor with a 940-microfarad capacitance and the second capacitor SC is an electric double-layer capacitor having a 100-millifarad capacitance. The stored duration T1 of the real-time clock is 7200 seconds, the threshold voltage MC_V_TH is 2.9 volts, and the stored voltage-threshold SC_V_TH is 2.8 volts. In some embodiments, the duration of the first capacitor's charging cycle is one second and the conduction duration of the second switch S2 is two milliseconds.

In an alternative embodiment, shown in FIG. 8, the second store 31 powers the real-time clock instead. As a result, the battery is no longer needed. This makes the meter fully energy-autonomous.

As long as the second store 31 has not been completely discharged, the meter operates in a manner identical to that in which a battery powers the real-time clock. On the other hand, if the second store 31 is completely discharged, for example as a result of the meter not having been active for an extended period, the microprocessor UC initializes the clock upon powering-on the meter. The instant indicated by the clock upon being powered on will then be considered the instant from which the stored duration T1 will be computed for determining when to send a new message on the long-range network.

The meter as described herein is simple to implement, reliable, and permits transmission of data concerning energy consumption over a long-range network, thereby dispensing with the need for a local station for centralizing messages. In addition, the meter permits management of message transmission on a short-range network, a long-range network, or both. The meter also avoids the need to rely on an external energy source, such as a battery. Instead, the meter is autonomous. The presence of a near-field communication link also permits direct access at any time and permits obtaining up-to-date values of energy index and configuration of the meter.

Although the meter can benefit from the use of a clock, it does not actually require the use of a real-time clock.

The meter as described herein permits an energy-sum message that comprises the most-recently computed energy index to be sent directly. This means that even if communication is interrupted, a receiver will receive an up-to-date index.

The meter as described herein also access to other physical quantities that are potentially available by virtue of sensors connected to the processing unit UC. Such quantities include, for example, temperature, humidity, pressure, acceleration, and presence and concentration of gases, such as carbon monoxide or carbon dioxide.

1-16. (canceled)

17. An apparatus comprising a meter for measuring consumption of electrical energy and carrying out wireless transmission of data representative of current that flows through a conductor, said apparatus comprising a current sensor, a first store, a threshold detector, a processor, a first switch, a second switch, a first wireless-transmitter, a first energy store, a second energy store, and a voltage meter, wherein said current sensor uses a primary current flowing through said conductor to induce a secondary current, wherein said first store connects to said current sensor and stores energy from said secondary current, wherein said threshold detector connects to said first store to determine when a voltage across terminals of said first store exceeds a threshold voltage, wherein said threshold detector controls said first switch and causes said first switch to permit power to be provided to said processor from said first store when said voltage across said terminals of said first store has exceeded said threshold voltage, wherein said second store connects to said first store, wherein said processor causes said second switch to trigger energy transfer from said first store to said second store thereby causing power to be supplied to said first wireless-transmitter when said voltage meter determines that a voltage across terminals of said second store exceeds a threshold and causes said first wireless-transmitter to transmit a message containing data representing said primary current to be transmitted.

18. The apparatus of claim 17, said apparatus further comprising a non-volatile memory, wherein said processor is a microprocessor in communication with said memory, and wherein said microprocessor increments an energy meter on completion of each charging cycle of said first store.

19. The apparatus of claim 18, further comprising a second wireless-transmitter connected to said processor, wherein microprocessor is configured to instruct a message to be transmitted using said second transmitter on completion of a charging cycle of said first store.

20. The apparatus of claim 18, wherein said second wireless-transmitter is configured to operate on a short-range network selected from the group consisting of Zigbee, ZigBee Green Power, Bluetooth, “Bluetooth Low Energy” or Wi-Fi.

21. The apparatus of claim 17, wherein said first wireless-transmitter is configured to operate on a long-range network of LPWAN type.

22. The apparatus of claim 17, further comprising a discharger connected to said first store, wherein said processor is configured to cause said discharger to discharge said first store.

23. The apparatus of claim 17, wherein said processor is configured to determine a data item representing a duration.

24. The apparatus of claim 23, wherein said data item representing a duration is a value indicative of a number of charging cycles of said first store.

25. The apparatus of claim 23, further comprising a clock, thereby permitting a data item representing a duration to be transmitted.

26. The apparatus of claim 17, wherein said second store comprises a super-capacitor.

27. The apparatus of claim 17, further comprising a rectifier connected to said current sensor, wherein said rectifier is configured to rectify said secondary current.

28. The apparatus of claim 17, further comprising a near-field communication circuit connected to a memory of said processor.

29. A method for metering consumption of electrical energy, said method comprising using an induced current, charging a first store, thereby causing said first store to store electrical energy, transferring energy stored in said first store to a second store when a voltage across terminals of said first store reaches a pre-determined threshold, and using a transmitter, transmitting a message when both data representing a duration has reached a threshold value and when a voltage at terminals of said second store has exceeded a pre-determined threshold.

30. The method of claim 29, wherein said data item representing a duration corresponds to a count of the number of charging cycles experienced by said first store.

31. The method as claim 29, wherein said data item representing a duration corresponds to an elapsed time as determined by using a clock.

32. The method of claim 29, further comprising discharging said first store after having either transferred energy from said first store to said second store or after having transmitted said message.
